(19) United States
(12) Patent Application Publication
(10) Pub. No.: US 2008/0138502 A1
(43) Pub. Date: Jun. 12, 2008

(54) METHOD FOR THE PRODUCTION OF AN SIN:H LAYER ON A SUBSTRATE

(76) Inventors: Roland TRASSL, Giessen (DE); Andreas Sauer, Grossostheim (DE); Stephan Wieder, Frankfurt (DE)

Correspondence Address: COOLEY GODWARD KRONISH LLP;ATTN: Patent Group, Suite 1100, 777 - 6th Street, NW, WASHINGTON, DC, 20001, US

(21) Appl. No.: 11/945,693

(22) Filed: Nov. 27, 2007

(30) Foreign Application Priority Data
Dec. 11, 2006 (EP) EP 06 125 817.4

(51) Int. Cl. C23C 14/34; B32B 1/02

(52) U.S. Cl. 427/74; 428/34.1

(57) ABSTRACT

The invention relates to a method for the production of an SiN:H layer on a substrate which converts light into electric voltage, wherein a silicon-containing target is sputtered and at least one reactive gas in introduced into the volume between target and substrate. The silicon-containing target is implemented in the form of a tube and is comprised of an Si-based alloy with an Al content of 2 to 50 wt. %.

The present application claims priority to commonly owned and assigned European Application No. EP 06 125 817.4, dated Dec. 11, 2006 and entitled Method for the Production of an SiN:H Layer on a Substrate, which is incorporated herein by reference.

### FIELD OF THE INVENTION

The present invention relates to a method for the production of an SiN:H layer on a substrate as well as the use of a pipe target with an Si-based alloy for the production of an SiN:H layer on a solar cell.

### BACKGROUND OF THE INVENTION

Electric energy can be obtained directly from sunlight by means of photovoltaic elements. The photovoltaic effect is based on the generation of an electromotive force through the absorption of ionizing radiation. Devices which utilize the photovoltaic effect in order to generate an electric voltage with the aid of sunlight, are referred to as solar cells. Solar cells must be differentiated from photoelectric cells which change their electric resistance upon irradiation with light and are used as light measuring instruments in cameras. Such photoelectric cells do not generate electric energy and require batteries to make them operable.

Solar cells have been in existence since approximately 1955. They were initially utilized in satellites and later, from 1960 to 1970, also in terrestrial systems. Since 1975 solar cells are largely applied in terrestrial systems. As a rule, they are comprised of a semiconductor material, preferably of silicon. However, semiconductors such as GaAs or CdTe (cadmium telluride) are also to be considered.

In principle, the solar cell effect also occurs in a combination of two different materials, for example in a combination of a metal and a semiconductor.

In order for an electric voltage to be generated from solar radiation, three processes must take place. First, a photon must be absorbed in the active portion of the material and cause electrons to be raised to a higher energy level. The charge carriers, which have been generated through the absorption, must subsequently be physically separated and be transported to the edges of the solar cells. Lastly, the charge carriers must be conducted out of the solar cells and sent to a consumer, before they can be recombined.

The efficiency of a solar cell is higher, the greater the quantity of captured light converted into electric energy. For example, it must be avoided that the light incident on the solar cell is reflected.

In order for light reflection to be decreased or excluded, solar cells are provided with a coating comprised of a dielectric material. Dielectric layers are nearly absorption-free and are suitable for the redistribution of the energy between reflection and transmission if they are interposed between two media—for example solar cell and air.

As a rule, in solar cells which are comprised of multicrystalline silicon, as an antireflection layer a material of SiNₓ:H is used. This silicon nitride doped with hydrogen has a low degree of reflection and a low degree of absorption, such that it transmits the incident light nearly completely.

The hydrogen-containing silicon nitride is conventionally applied onto the solar cells by means of a PECVD method (PECVD=Plasma Enhanced Chemical Vapor Deposition).

It is also known to apply SiN:H antireflection layers onto solar cells by means of sputtering (Wolke et al.: SiN:H Anti-Reflection Coatings for C—Si Solar Cells by Large Scale Inline Sputtering, 19th European Photovoltaic Solar Energy Conference, 7-11 Jun. 2004, Paris, pp. 419-422). In this method planar targets of silicon are sputtered and a reactive gas of nitrogen and hydrogen or ammonia is introduced into the sputter chamber such that SiNₓ:H is formed from the sputtered silicon and the reactive gas. The silicon utilized must be highly pure since, for example, contaminations with iron or copper can diffuse into the absorber and can thus reduce the efficiency.

As a rule, planar targets are less efficient than rotating pipe targets since approximately 75% of the target material in the case of planar targets cannot be utilized for the layer generation. Pipe targets, on the other hand, are more difficult to produce than planar targets, and specifically so in the case of pipe targets of doped silicon.

A method for the production of a tubular sputter target of an Si-based alloy with an Al content of 5 to 50 wt. % is also known (DE 102 53 319 B3). In this method the target material is produced in casting processes by melting and casting the material under vacuum, the casting taking place in a hollow cylindrical casting mold with a graphite core.

The invention addresses the problem of increasing the effectiveness when applying an antireflection layer of SiN:H onto solar cells.

This problem is solved according to the features of patent claim 1.

### SUMMARY OF THE INVENTION

The invention relates to a method for the production of an SiN:H layer on a substrate which converts light into electric voltage, wherein a silicon-containing target is sputtered and at least one reactive gas in introduced into the volume between target and substrate. The silicon-containing target is implemented in the form of a tube and is comprised of an Si-based alloy with an Al content of 2 to 50 wt. %.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 illustrates a target and substrate in accordance with one embodiment of the present invention; and

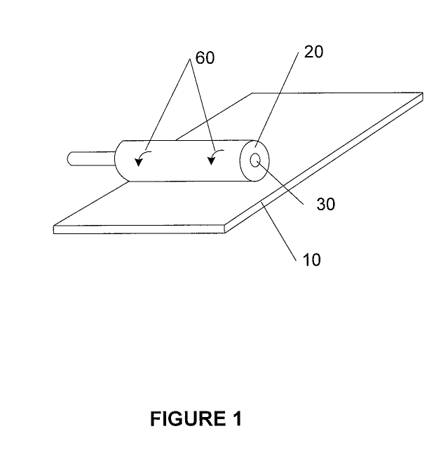

FIG. 2 is an exemplary target constructed in accordance with one embodiment of the present invention.

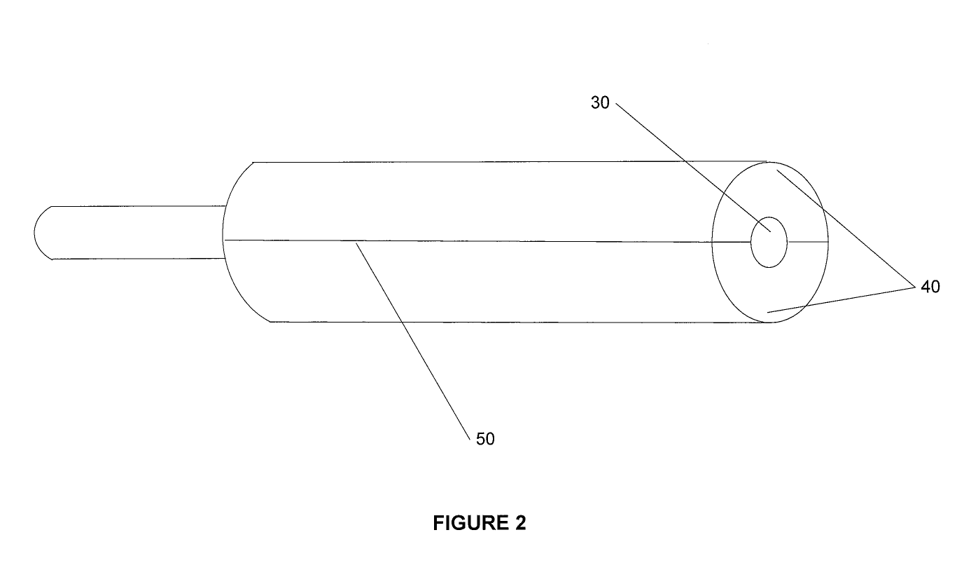

### DETAILED DESCRIPTION

The invention consequently relates to a method for the production of an SiN:H layer on a substrate 10 which converts light into electric voltage, wherein a silicon-containing target 20 is sputtered and at least one reactive gas is introduced into the volume between target and substrate (not shown). The silicon-containing target 20 is here implemented in the form of a tube and is comprised of an Si-based alloy with an Al content of 2 to 50 wt. %.

The advantage achieved with the invention comprises in particular that, in comparison with planar targets, the service life of the sputter installation is increased due to the greater material supply. In addition, the costs for the production of the solar cells are lowered. As has unexpectedly been found, the addition of aluminum to silicon impairs minimally the optical properties of the layer sputtered onto the solar cell.

In an advantageous embodiment of the invention the Al content is 2 to 50 wt. %.

In a further advantageous embodiment of the invention, the tubular target is formed of two half-tubes 40, which are fastened on a support tube 30.

In a further advantageous embodiment of the invention the fastening of the two half-tubes takes place by means of adhesive 50.

In a further advantageous embodiment of the invention the tubular target is rotated 60 about its longitudinal axis during the sputter operation.

In a further advantageous embodiment of the invention of the invention the reactive gas consists of hydrogen and nitrogen or is comprised of hydrogen and nitrogen.

In a further advantageous embodiment of the invention the reactive gas is or comprises ammonia.

In a further advantageous embodiment of the invention the target 20 is comprised of silicon.

In a further advantageous embodiment of the invention the target 20 is comprised of GaAs.

In a further advantageous embodiment of the invention the target 20 is comprised of CdTe.

If the SiN:H layer on a solar cell is produced by means of sputtering, it is advantageous to utilize a pipe target 20 comprised of an Si-based alloy with an Al content of 2 to 50 wt. %.

In conclusion, the present invention provides, among other things, a method for the production of an SiN:H layer on a substrate as well as the use of a pipe target with an Si-based alloy for the production of an SiN:H layer on a solar cell. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A method for the production of an SiN:H layer on a substrate which converts light into electric voltage, the method comprising:
sputtering a target comprising silicon, wherein the target is implemented in the form of a tube and is comprised of an Si-based alloy with an Al content of 2 to 50 wt. %.
introducing at least one reactive gas into the volume between the target and a substrate.

2. The method as claimed in claim 1, wherein the Al content is 2 to 10 wt. %.

3. The method as claimed in claim 1, wherein the tubular target is formed of two half tubes which are fastened on a support tube.

4. The method as claimed in claim 3, wherein the fastening of the two half tubes takes place by means of an adhesive.

5. The method as claimed in claim 1, wherein the tubular target is rotated about its longitudinal axis during the sputter operation.

6. The method as claimed in claim 1, wherein the reactive gas comprises hydrogen and nitrogen.

7. The method as claimed in claim 1, wherein the reactive gas comprises ammonia.

8. The method as claimed in claim 1, wherein the target is comprised of silicon.

9. The method as claimed in claim 1, wherein the target is comprised of GaAs.

10. The method as claimed in claim 1, wherein the target is comprised of CdTe.

11. A pipe target for use in sputtering, the pipe target comprising an Si-based alloy with an Al content of 2 to 50 wt. %.

12. A method for production of an SiN:H layer on a solar cell, the method comprising:
sputtering a pipe target onto a substrate wherein the target is comprised of an Si-based alloy with an Al content of 2 to 50 wt. %.
